(19) United States
(12) Patent Application Publication
(10) Pub. No.: US 2004/0238926 A1
(43) Pub. Date: Dec. 2, 2004

(54) Semiconductor wafer, semiconductor device and method for manufacturing same, circuit board, and electronic apparatus

(75) Inventor: Takayoshi Obinata, Nagano-ken (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/801,107

(22) Filed: Mar. 15, 2004

(30) Foreign Application Priority Data
Mar. 20, 2003 (JP) 2003-078097

(51) Int. Cl. H01L 29/74

(52) U.S. Cl. 257/678

(57) ABSTRACT

A semiconductor device includes a semiconductor chip including an integrated circuit, an interconnect electrically connected to the integrated circuit, a pad that is a part of the interconnect and disposed on a front surface of the semiconductor chip, wirings electrically connected to the pad, an external terminal provided over and electrically connected to the wirings and a resin layer surrounding the external terminal and extending to a side face of the semiconductor chip.

### BACKGROUND OF THE INVENTION

1. Technical Field of the Invention

The present invention relates to a semiconductor wafer, a semiconductor device and a method for manufacturing the same, a circuit board, and an electronic apparatus.

2. Description of Related Art

Bare-chip mounting is one type of high-density packaging that has been studied. In bare-chip mounting, however, it is difficult to ensure quality and handling. For this reason, semiconductor devices that employ Chip Scale/Size Packages (CSP)s have been developed. In particular, wafer-level CSPs has received attention recently. In wafer-level CSPs, packaging including the formation of a resin layer is performed at the wafer level. The wafer is then sectioned into individual packages. The resin layer may also be cut out during this step. In that case, the sectioned resin layer is undesirably liable to delaminate at the cutting plane.

It is an advantage of the present invention to prevent or inhibit the delamination of the resin layer.

### SUMMARY OF THE INVENTION

A semiconductor device according to an embodiment of the present invention includes a semiconductor chip that includes an integrated circuit, an interconnect electrically connected to the integrated circuit, and a pad that is a part of the interconnect and is disposed on a front surface of the semiconductor chip. A wiring is electrically connected to the pad. An external terminal is provided over and electrically connected to the wiring. A resin layer surrounds the external terminal and extends to a side face of the semiconductor chip. According to the present invention, the resin layer extends to a side face of the semiconductor chip and therefore is resistant to delamination. In addition, since the resin layer extends to the side face of the semiconductor chip, even when the resin layer shrinks, the resin layer has good adhesion to the semiconductor chip.

According to an embodiment of the semiconductor device, the semiconductor chip has a thin-wall part at edges thereof and the resin layer extends to the thin-wall part. Also the semiconductor chip has a first face perpendicularly descending from the front surface, a second face perpendicularly ascending from the back surface opposite to the front surface, and a third face that is parallel to the front surface and connects the first face with the second face. The resin layer is formed on the first face, but not on the second face.

According to an embodiment of the present invention, the semiconductor chip may have a first face perpendicularly descending from the front surface, a second face perpendicularly ascending from the back surface opposite to the front surface, and a third face that curves to connect the first face with the second face, and the resin layer may be formed on the first face, but not on the second face. The resin layer may also be formed on the third face.

In the semiconductor device, the semiconductor chip may include a first face descending from the front surface and a second face ascending from the back surface opposite to the front surface, the first face and the second face being formed at different angles, and the resin layer may be formed on the first face, but not on the second face. The semiconductor chip may also include a first face curvedly descending from the front surface and a second face vertically ascending from the back surface opposite to the front surface, and the resin layer may be formed on the first face, but not on the second face. The semiconductor device may further include a stress relaxation layer formed on the semiconductor chip, wherein the wiring may be formed on the stress relaxation layer and the resin layer may be formed over the stress relaxation layer. In addition, the semiconductor device may further include a resist layer that covers the wirings other than a region for providing the external terminal, wherein the resin layer may be formed over the resist layer.

A circuit board according to the present invention includes the above-described semiconductor device and an electronic apparatus according to the present invention has the above-described semiconductor device.

According to another embodiment of the present invention, the semiconductor wafer includes a semiconductor substrate that includes a plurality of integrated circuits, an interconnect electrically connected to each of the integrated circuits, and pads that are part of the interconnect on a front surface of the semiconductor substrate, wherein grooves are formed in the front surface. Wirings are electrically connected to the pads. External terminals are provided over and electrically connected to the wiring. A resin layer surrounds the external terminals and covers the grooves. According to the present invention, since the resin layer extends to the groove, it has good adhesion to the semiconductor substrate and is resistant to delamination.

According to the present invention, the grooves may surround each of the integrated circuits, a side face and the bottom face of each groove may be connected via a curved surface, and the side face of each groove may be inclined.

The semiconductor wafer may further include a stress relaxation layer formed on the semiconductor substrate, wherein the wirings may be formed on the stress relaxation layer and the resin layer may be formed over the stress relaxation layer.

The semiconductor wafer may further include a resist layer that covers the wirings other than a region for providing the external terminal, wherein the resin layer may be formed over the resist layer.

A method for manufacturing a semiconductor device according to the present invention includes forming grooves on a front surface of a semiconductor substrate that includes a plurality of integrated circuits, with an interconnect electrically connected to each of the integrated circuits, and a pad that is a part of the interconnect on the front surface of the semiconductor substrate. The method also includes forming wirings so as to be electrically connected with the pad, providing an external terminal over the wirings so as to be electrically connected with the wirings, providing a resin layer so as to surround the external terminal and cover the grooves and thereafter, cutting the semiconductor substrate together with the resin layer in the grooves. According to the present invention, the resin layer provided on the semiconductor substrate is designed to extend to the grooves. When the semiconductor substrate and the resin layer are cut along the grooves, the resin layer adheres to a side face of the grooves. Thus, this prevents the resin layer from delamination.

In the method for manufacturing the semiconductor device, the grooves may be formed so as to surround each of the integrated circuits, the grooves may be each formed such that a side face and the bottom face thereof are connected via a curved surface and the grooves may be each formed such that a side face thereof is inclined.

The method for manufacturing a semiconductor device according to the present invention may further include forming a stress relaxation layer on the semiconductor substrate before forming wirings wherein the wirings are formed on the stress relaxation layer and the resin layer is formed over the stress relaxation layer.

The method for manufacturing a semiconductor device according to the present invention may further include forming a resist layer before providing an external terminal so as to cover the wirings other than a region for providing the external terminal, wherein the resin layer is formed over the resist layer.

### BRIEF DESCRIPTION OF THE DRAWINGS

FIG. 1 is a diagram illustrating the method for manufacturing a semiconductor device according to a first embodiment of the present invention.

FIG. 2 is a diagram illustrating the shape of a groove.

FIG. 3 is a diagram illustrating the method for manufacturing a semiconductor device according to the first embodiment of the present invention.

FIG. 4 is a diagram illustrating the method for manufacturing a semiconductor device according to the first embodiment of the present invention.

FIG. 5 is a diagram illustrating a semiconductor device according to the first embodiment of the present invention.

FIG. 6 is an enlarged view of a section taken along the line VI-VI in FIG. 5.

FIG. 7 is a diagram illustrating the method for manufacturing a semiconductor device according to a second embodiment of the present invention.

FIG. 8 is a diagram illustrating a semiconductor device according to the second embodiment of the present invention.

FIG. 9 is a diagram illustrating the method for manufacturing a semiconductor device according to a third embodiment of the present invention.

FIG. 10 is a diagram illustrating a semiconductor device according to the third embodiment of the present invention.

FIG. 11 is a diagram illustrating the method for manufacturing a semiconductor device according to a fourth embodiment of the present invention.

FIG. 12 is a diagram illustrating a semiconductor device according to the fourth embodiment of the present invention.

FIG. 13 is a diagram illustrating the method for manufacturing a semiconductor device according to a fifth embodiment of the present invention.

FIG. 14 is a diagram illustrating a semiconductor device according to the fifth embodiment of the present invention.

FIG. 15 is a diagram illustrating a circuit board on which a semiconductor device according to the present invention is mounted.

FIG. 16 is a diagram showing an electronic apparatus with a semiconductor device according to the present invention.

FIG. 17 is a diagram showing an electronic apparatus having a semiconductor device according to the present embodiment.

### DETAILED DESCRIPTION OF THE PREFERRED EMBODIMENTS

Embodiments of the present invention will now be illustrated with reference to the drawings.

First Embodiment

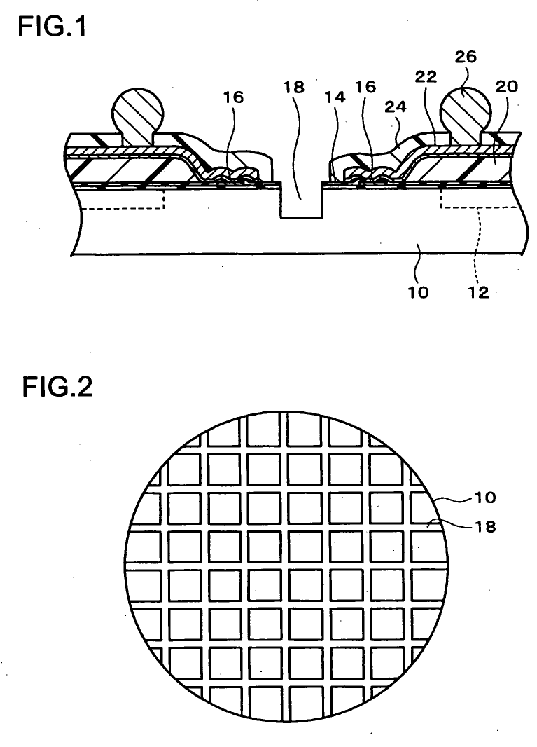

FIGS. 1 to 4 illustrate a method for manufacturing a semiconductor device according to a first embodiment of the present invention. In this embodiment, a semiconductor substrate 10 is used. The semiconductor substrate 10 includes an integrated circuit 12. When the semiconductor substrate 10 is sectioned into a plurality of semiconductor chips, a plurality of integrated circuits 12 are formed in the semiconductor substrate 10. Therefore, individual semiconductor chips will have their respective integrated circuits 12.

On the front surface of the semiconductor substrate 10, a passivation film 14 may be formed. For example, the passivation film 14 may be formed from an inorganic material, such as SiO₂ or SiN. The passivation film 14 may be formed in multiple layers. In this case, at least one layer (for example, a surface layer) may be formed from an organic material.

A pad 16 is formed on (the surface of) the semiconductor substrate 10. The pad 16 is a part (for example, an edge) of an interconnect that is electrically connected to the integrated circuit (for example, a semiconductor integrated circuit) 12. The passivation film 14 is not formed at least in the center of the pad 16.

In this embodiment, grooves 18 are formed in the semiconductor substrate 10 (the front surface on which the pad 16 is formed). As shown in FIG. 2, the grooves 18 may have a grid pattern. The grooves 18 may surround each of the integrated circuits 12. The grooves 18 may be formed before or after the formation of a stress relaxation layer 20 and a resist layer 24, described below.

As shown in FIG. 1, a stress relaxation layer 20 may be formed on the semiconductor substrate 10. The stress relaxation layer 20 may be formed by applying a resin precursor (for example, a thermosetting resin precursor) on the semiconductor substrate 10 or by spin-coating of the resin precursor over the semiconductor substrate 10. The stress relaxation layer 20 may be formed in a single layer or multiple layers. The stress relaxation layer 20 is an electrically insulating layer. The stress relaxation layer 20 may be formed from polyimide resins, silicone-modified polyimide resins, epoxy resins, silicone-modified epoxy resins, benzocyclobutene (BCB), polybenzoxazole (PBO), or the like. The stress relaxation layer 20 does not contain electrically conductive particles. The stress relaxation layer 20 may be formed from a material having a light blocking effect.

The stress relaxation layer 20 may be formed from a radiation-sensitive resin precursor that is sensitive to radiation (light (ultraviolet light, visible light), X-rays, an electron beam). Radiation-sensitive resin precursors (for example, a photosensitive resin precursor) are classified into a negative type, an irradiated part of which has reduced solubility and becomes insoluble, and a positive type, an irradiated part of which has increased solubility.

The stress relaxation layer 20 may not be formed on the pad 16. The stress relaxation layer 20 is not formed on the grooves 18 (so as not to enter the grooves 18). The stress relaxation layer 20 may not be formed on a sectioning region of the semiconductor substrate 10. The stress relaxation layer 20 may be formed continuously or integrally on the semiconductor substrate 10 before patterning. In this case, the stress relaxation layer 20 may temporarily be formed in the grooves 18 before patterning. The stress relaxation layer 20 may be formed in each of multiple regions (a plurality of regions provided with integrated circuits 12) of the semiconductor substrate 10. A space is present between adjacent stress relaxation layers 20.

Wirings 22 are formed on the stress relaxation layer 20. The wiring 22 may be formed in a single layer or multiple layers. For example, a TiW layer and a Cu layer may be laminated by sputtering, and another Cu layer may be formed thereon by plating. Conventional techniques may be applied to the method for forming them. The wirings 22 extends over the pad 16 (so as to be electrically connected to the pad 16). The wirings 22 are formed over the pad 16 and the stress relaxation layer 20. The wirings 22 may have a land (a portion that is wider than a line). The land is a portion for providing an external terminal 26 thereon.

A resist layer 24 may be formed on the stress relaxation layer 20. The resist layer 24 may be a solder resist. The resist layer 24 may cover the entire or part (for example, a portion excluding a region for providing the external terminal 26) of the wirings 22. The resist layer 24 may cover (for example, completely cover) the stress relaxation layer 20. The resist layer 24 may be formed such that a sectioning region of the semiconductor substrate 10 is exposed (so as to avoid the sectioning region). The resist layer 24 is not formed on the grooves 18 (so as not to enter the grooves 18). The resist layer 24 may be formed continuously or integrally on the semiconductor substrate 10 before patterning. In this case, the resist layer 24 may temporarily be formed in the grooves 18 before patterning. The resist layer 24 may be formed in each of multiple regions (a plurality of regions that includes integrated circuits 12) of the semiconductor substrate 10. A space is present between adjacent resist layers 24.

An external terminal 26 is formed on (or over) the wirings 22. The external terminal 26 may be formed with a soft solder or a hard solder. The soft solder may be free of lead (hereinafter referred to as a lead-free solder). Examples of the lead-free solder may include tin-silver (Sn—Ag), tin-bismuth (Sn—Bi), tin-zinc (Sn—Zn), or tin-copper (Sn—Cu) alloys. In addition, these alloys may further contain at least one of silver, bismuth, zinc, and copper. Conventional methods may be applied to forming the external terminal 26.

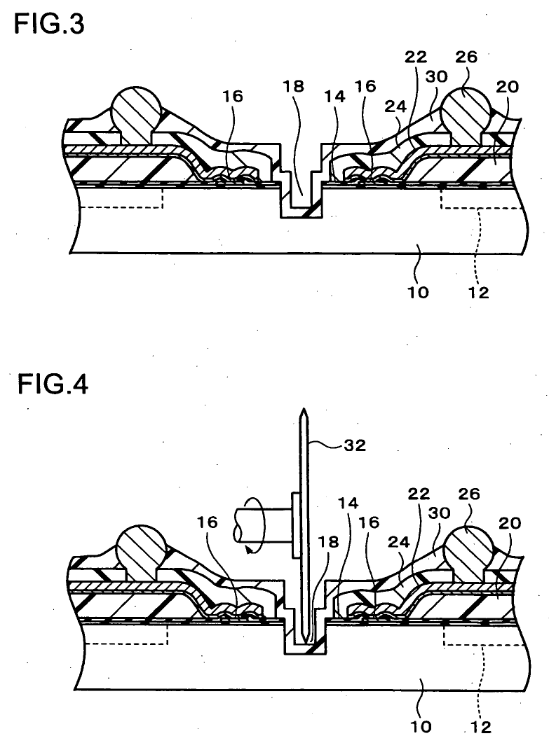

As shown in FIG. 3, a resin layer 30 is formed on the resist layer 24. The description on the stress relaxation layer 20 may be applied to the resin layer 30. The resin layer 30 may cover the grooves 18. The surface of the resin layer 30 may sink at the region inside the grooves 18. The resin layer 30 surrounds the external terminal 26. The resin layer 30 may cover a part (for example, the basal portion) of the external terminal 26. The resin layer 30 may cover (for example, completely cover) the resist layer 24. The resin layer 30 may cover the entire semiconductor substrate 10 before patterning. The resin layer 30 may be provided so as to cover the external terminal 26 and then removed from the top edge of the external terminal 26. The description on the pattering of the stress relaxation layer 20 may also be applied to this patterning. Alternatively, the resin layer 30 may be partly removed by laser irradiation or ashing.

A semiconductor wafer according to the embodiment of the present invention includes the semiconductor substrate 10. The semiconductor substrate 10 has the plurality of integrated circuits 12 (see FIG. 1) and the pads 16 on the front surface thereof. Each pad 16 is a part of the interconnect that is electrically connected to each integrated circuit 12. The grooves 18 are formed in the semiconductor substrate 10. The wirings 22 are electrically connected to the pads 16. Over the wirings 22, the external terminals 26 are electrically connected to the wirings 22. The resin layer 30 surrounds the external terminals 26. The resin layer 30 covers the grooves 18. The other details are as described above. According to this embodiment, the resin layer 30 is designed to extend to the grooves 18. Therefore, the resin layer 30 has good adhesion to the semiconductor substrate 10 and is resistant to delamination.

As shown in FIG. 4, the semiconductor substrate 10 is sectioned (for example, by scribing or dicing) with, for example, a cutter (or a blade) 32. The semiconductor substrate 10 and the resin layer 30 are sectioned together. The sectioning is performed within the grooves 18. Even when the semiconductor substrate 10 and the resin layer 30 are sectioned, the resin layer 30 is designed to extend to a side face of each groove 18 and therefore the delamination of the resin layer 30 can be prevented. Thus, a semiconductor device can be prepared.

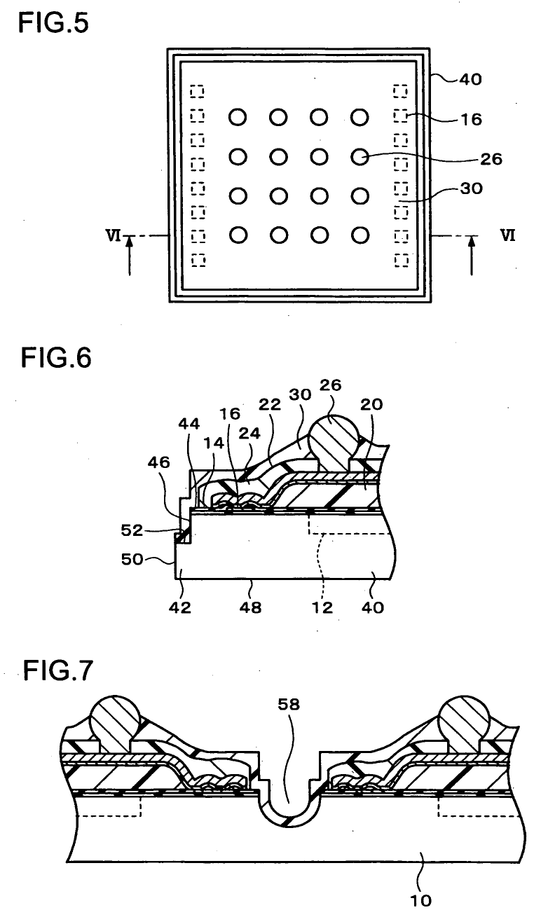

FIG. 5 shows a semiconductor device according to the present embodiment. FIG. 6 is a section taken along the line VI-VI in FIG. 5. The semiconductor device includes a semiconductor chip 40. The semiconductor chip 40 may be cut from the semiconductor substrate 10. The semiconductor chip 40 has the integrated circuit 12 (see FIG. 1) and the pads 16 on the front surface. The pads are parts of the interconnect that are electrically connected to the integrated circuit 12. The stress relaxation layer 20 is formed on the semiconductor chip 40. The wirings 22 that are electrically connected to the pads 16 are formed on the stress relaxation layer 20. External terminals 26 that are electrically connected to the wirings 22 are formed over the wirings 22. The semiconductor device includes the resin layer 30. The resin layer 30 surrounds the external terminals 26. The resin layer 30 extends to a side face of the semiconductor chip 40.

The semiconductor chip 40 has a thin-wall part 42 at edges thereof. Specifically, the semiconductor chip 40 has a first face 46 perpendicularly descending from a front surface 44 on which the pads 16 are formed, a second face 50 perpendicularly ascending from the back surface 48 opposite to the front surface 44, and a third face 52 that is parallel to the front surface 44 and connects the first face 46 with the second face 50. The resin layer 30 extends on the thin-wall part 42. The resin layer 30 may be formed on the first face 46, but not on the second face 50. The resin layer 30 may also be formed on the third face 52. The other details are as described above.

According to the present embodiment, the resin layer 30 extends to a side face of the semiconductor chip 40 and thus reduces delamination. In addition, since the resin layer 30 is designed to extend to the side face of the semiconductor chip 40, even when the resin layer 30 shrinks, it has good adhesion to the semiconductor chip 40.

Second Embodiment

FIG. 7 shows a method for manufacturing a semiconductor device according to a second embodiment of the present invention. In the present embodiment, the shape of a groove 58 formed in a semiconductor substrate 10 is different from the groove 18 described in the first embodiment. Except for that, the description given in the first embodiment is applicable to this embodiment. The groove 58 is, for example, a U-shaped groove or a round (semi-circular) groove. The bottom face of the groove 58 is a curved surface. The side faces of the groove 58 may be curved or may be formed at an angle. The groove 58 is formed such that the side faces and the bottom face are connected via the curved surface. In the present embodiment, the grooves 58 are formed in the semiconductor substrate 10, and then the steps described in the first embodiment are followed to yield a semiconductor device. Note that the bottom face and the side faces of the grooves 58 are connected via the curved surface (without an edge), and thereby hardly any gap is formed between a resin layer 68 and the groove 58.

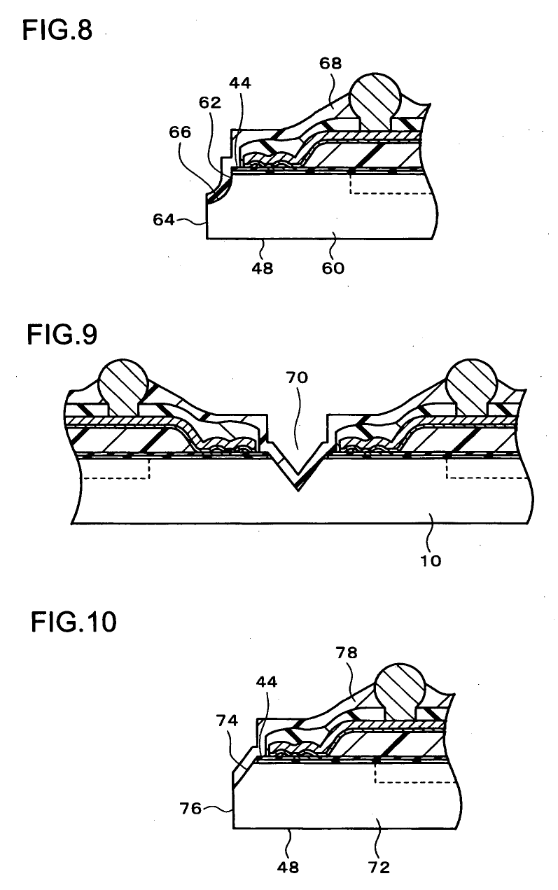

FIG. 8 shows the semiconductor device prepared from the semiconductor substrate shown in FIG. 7. When the groove 58 is a U-shaped groove, a first face 62 will descend perpendicularly from a front surface 44 of a semiconductor chip 60. When the groove 58 is a round (semi-circular) groove, the first face 62 will descend in a curved manner from the front surface 44 of the semiconductor chip 60. A second face 64 ascends perpendicularly from a back surface 48 opposite to the front surface 44. A third face 66 curves to connect the first face 62 with the second face 64. The resin layer 68, to which the description of the resin layer 30 is applicable, is formed on the first face 62, but not on the second face 64. The resin layer 68 may also be formed on the third face 66. The description in the first embodiment is applicable to the other details.

Third Embodiment

FIG. 9 shows a method for manufacturing a semiconductor device according to a third embodiment of the present invention. In the present embodiment, the shape of a groove 70 formed in a semiconductor substrate 10 is different from the groove 18 described in the first embodiment. Except for that, the description given in the first embodiment is applicable to this embodiment. The groove 70 is, for example, a V-shaped groove. The side faces of the groove 70 are formed at an angle. In the present embodiment, the groove 70 is formed in the semiconductor substrate 10, and then the steps described in the first embodiment are followed to yield a semiconductor device.

FIG. 10 shows the semiconductor device prepared from the semiconductor substrate shown in FIG. 9. In this semiconductor device, a semiconductor chip 72 has a first face 74 that descends from a front surface 44, and a second face 76 that ascends from a back surface 48 opposite to the front surface 44. The first face 74 and the second face 76 are formed at different angles relative to the front surface 44. A resin layer 78, to which the description of the resin layer 30 is applicable, is formed on the first face 74, but not on the second face 76. The description in the first embodiment is applicable to the other details.

Fourth Embodiment

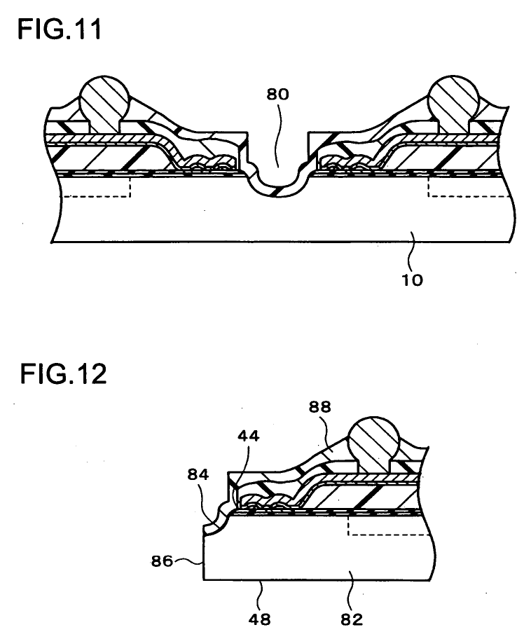

FIG. 11 shows a method for manufacturing a semiconductor device according to a fourth embodiment of the present invention. In the present embodiment, the shape of a groove 80 formed in a semiconductor substrate 10 is different from the groove 18 described in the first embodiment. Except for that, the description given in the first embodiment is applicable to this embodiment. The groove 80 is, for example, a curved groove. The bottom face of the groove 58 has a curved surface. The front surface of the semiconductor substrate 10 and the groove 80 are connected in a smooth manner via the curved surface. In the present embodiment, the groove 80 is formed in the semiconductor substrate 10, and then the steps described in the first embodiment are followed to yield a semiconductor device. Note that the bottom face and the side faces of the groove 80 are connected via the curved surface (without an edge), and thereby hardly any gap is formed between a resin layer 88 and the groove 80.

FIG. 12 shows the semiconductor device prepared from the semiconductor substrate shown in FIG. 11. In this semiconductor device, a semiconductor chip 82 has a first face 84 that descends in a curved manner from a front surface 44, and a second face 86 that ascends vertically from a back surface 48 opposite to the front surface 44. A resin layer 88, to which the description of the resin layer 30 is applicable, is formed on the first face 84, but not on the second face 86. The description in the first embodiment is applicable to the other details.

Fifth Embodiment

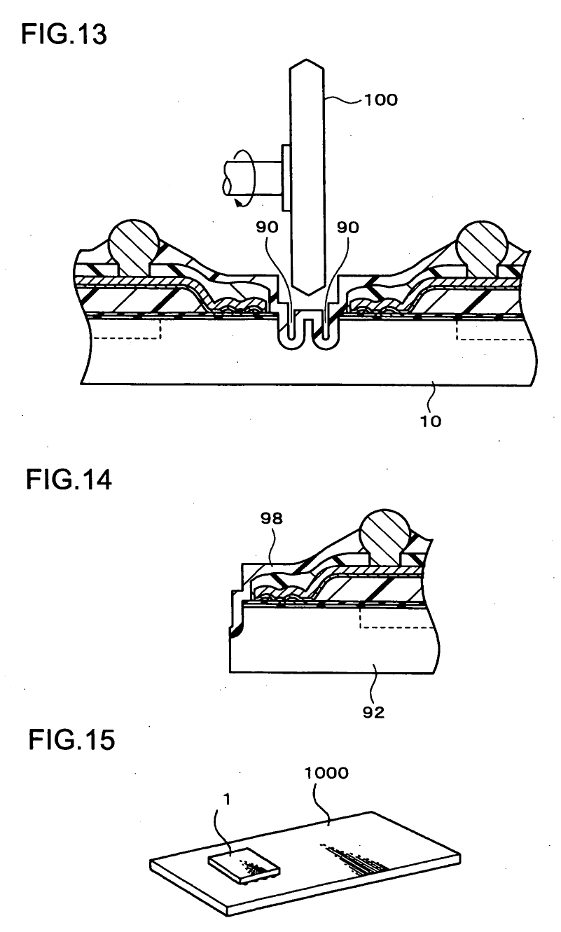

FIG. 13 shows a method for manufacturing a semiconductor device according to a fifth embodiment of the present invention. In the present embodiment, a plurality of (for example, two) grooves 90 are formed in parallel in a sectioning region of a semiconductor substrate 10. The plurality of grooves 90 may be simultaneously formed with a cutter that has a plurality of edges. Except for these details, the description given in the first embodiment is applicable to this embodiment. The descriptions of the groove given in the first to fourth embodiments are applicable to the shape of each groove 90. In the present embodiment, the grooves 90 are formed in a sectioning region of the semiconductor substrate 10, and then the steps described in the first embodiment are followed.

When the semiconductor substrate 10 is sectioned, a portion between the juxtaposed grooves 90 in the sectioning region should be removed. As shown in FIG. 13, the semiconductor substrate 10 may be sectioned with a relatively thick cutter 100 that has a thickness equal to or greater than the pitch between the juxtaposed grooves 90. Thus, a semiconductor device is prepared.

FIG. 14 shows the semiconductor device prepared from the semiconductor substrate shown in FIG. 13. A resin layer 98, to which the description of the resin layer 30 is applicable, extends to a side face of a semiconductor chip 92. The shape of an edge of the semiconductor chip 92 depends on the shape of each groove 90, and its details are as described in the first to fourth embodiments. The description in the first embodiment is applicable to the other details.

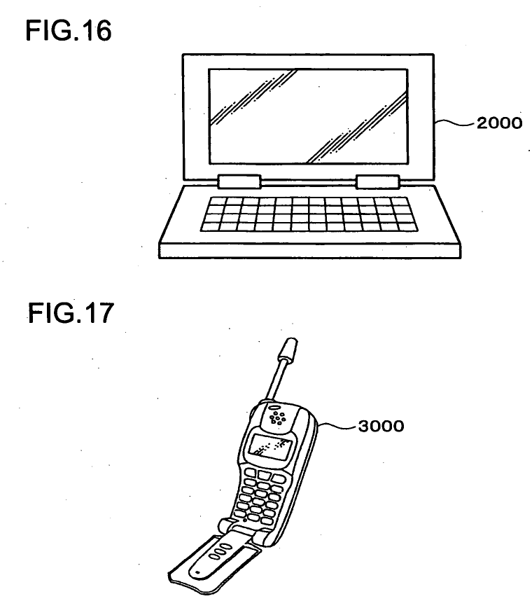

FIG. 15 shows a circuit board 1000 on which a semiconductor device 1 described in the above-mentioned embodiment is mounted. Examples of electronic apparatuses having this semiconductor device include a notebook personal computer 2000 shown in FIG. 16 and a cellular phone 3000 shown in FIG. 17.

The present invention is not limited to the above-described embodiments and various modifications can be made. For example, the present invention encompasses structures that are substantially identical to the structure described in the above embodiments (for example, a structure with the same function, method and results, or a structure with the same advantages and results). Furthermore, the present invention encompasses structures in which nonessential parts of the structures described in the embodiments are replaced. The present invention also encompasses structures that have the same effects or achieve the same advantages as those of the structures described in the embodiments. The present invention further encompasses structures in which known techniques are incorporated into the structures described in the embodiments.

What is claimed is:

1. A semiconductor device, comprising:
a semiconductor chip including an integrated circuit;
an interconnect electrically connected to the integrated circuit;
a pad that is a part of the interconnect and disposed on a front surface of the semiconductor chip;
wirings electrically connected to the pad;
an external terminal provided over and electrically connected to the wirings; and
a resin layer surrounding the external terminal and extending to a side face of the semiconductor chip.

2. The semiconductor device according to claim 1, wherein the semiconductor chip has a thin-wall part at edges thereof, and the resin layer extends to the thin-wall part.

3. The semiconductor device according to claim 2, wherein the semiconductor chip has a first face perpendicularly descending from the front surface, a second face perpendicularly ascending from a back surface opposite to the front surface, and a third face parallel to the front surface and connecting the first face with the second face, and the resin layer formed on the first face, but not on the second face.

4. The semiconductor device according to claim 2, wherein the semiconductor chip has a first face perpendicularly descending from the front surface, a second face perpendicularly ascending from a back surface opposite to the front surface, and a third face that curves to connect the first face with the second face, and the resin layer is formed on the first face, but not on the second face.

5. The semiconductor device according to claim 3, wherein the resin layer is also formed on the third face.

6. The semiconductor device according to claim 2, wherein the semiconductor chip comprises a first face descending from the front surface and a second face ascending from a back surface opposite to the front surface, the first face and the second face being formed at different angles, and the resin layer formed on the first face, but not on the second face.

7. The semiconductor device according to claim 2, wherein the semiconductor chip comprises a first face curved in a descending manner from the front surface and a second face vertically ascending from a back surface opposite to the front surface, and the resin layer formed on the first face, but not on the second face.

8. The semiconductor device according to claim 1, further comprising a stress relaxation layer formed on the semiconductor chip, wherein the wirings are formed on the stress relaxation layer and the resin layer is formed over the stress relaxation layer.

9. The semiconductor device according to claim 1, further comprising a resist layer covering the wirings other than a region for providing the external terminal, wherein the resin layer is formed over the resist layer.

10. A circuit board on which a semiconductor device according to claim 1 is mounted.

11. An electronic apparatus comprising a semiconductor device according to claim 1.

12. A semiconductor wafer, comprising:
a semiconductor substrate including a plurality of integrated circuits;
an interconnect electrically connected to each of the integrated circuits;
pads that are parts of the interconnect and disposed on a front surface of the semiconductor substrate, wherein grooves are formed in the front surface;
wirings electrically connected to the pads;
external terminals provided over and electrically connected to the wirings; and
a resin layer surrounding the external terminals and covering the grooves.

13. The semiconductor wafer according to claim 12, wherein the grooves surround each of the integrated circuits.

14. The semiconductor wafer according to claim 12, wherein a side face and a bottom face of each groove are connected via a curved surface.

15. The semiconductor wafer according to claim 12, wherein a face of each groove is inclined.

16. The semiconductor wafer according to claim 12, further comprising a stress relaxation layer formed on the semiconductor substrate, wherein the wirings are formed on the stress relaxation layer and the resin layer is formed over the stress relaxation layer.

17. The semiconductor wafer according to claim 12, further comprising a resist layer covering the wirings other than a region for providing the external terminals, wherein the resin layer is formed over the resist layer.

18. A method for manufacturing a semiconductor device, comprising:
(a) forming grooves in a front surface of a semiconductor substrate that includes a plurality of integrated circuits, an interconnect electrically connected to each of the integrated circuits, and a pad that is a part of the interconnect and disposed on the front surface of the semiconductor substrate;
(b) forming wirings so as to be electrically connected with the pad;
(c) providing an external terminal over the wiring so as to be electrically connected with the wirings;
(d) providing a resin layer so as to surround the external terminal and cover the grooves; and
(e) cutting the semiconductor substrate together with the resin layer in the grooves.

19. The method for manufacturing a semiconductor device according to claim 18, further comprising forming the grooves so as to surround each of the integrated circuits.

20. The method for manufacturing a semiconductor device according to claim 18, further comprising forming each of the grooves such that a side face and a bottom face of the grooves thereof are connected via a curved surface.

21. The method for manufacturing a semiconductor device according to claim 18, further comprising forming each of the grooves such that a side face thereof is inclined.

22. The method for manufacturing a semiconductor device according to claim 18, further comprising:
forming a stress relaxation layer on the semiconductor substrate before step (b);
forming the wirings on the stress relaxation layer in step (b); and
the resin layer forming over the stress relaxation layer in step (d).

23. The method for manufacturing a semiconductor device according to claim 18, further comprising:
forming a resist layer before step (c) so as to cover the wirings other than a region for providing the external terminal; and
forming the resin layer over the resist layer in step (d).
